(19) United States
(12) Patent Application Publication
(10) Pub. No.: US 2019/0267342 A1
(43) Pub. Date: Aug. 29, 2019

(54) Wafer Level UGA (UBM Grid Array) & PGA (Pad Grid Array) for Low Cost Package

(71) Applicant: Dialog Semiconductor B.V., s-Hertogenbosch (NL)

(72) Inventors: Shou Cheng Eric Hu, Taichung City (TW); Jesus Mennen Belonio, JR., Neubiberg (DE)

(21) Appl. No.: 15/907,446

(22) Filed: Feb. 28, 2018

(51) Int. Cl. H01L 23/00; H01L 21/78

(52) U.S. Cl. CPC H01L 24/05; H01L 24/03; H01L 21/78; H01L 24/89; H01L 2224/05562; H01L 2224/05008; H01L 2224/80801; H01L 2224/05082; H01L 2224/02381; H01L 2224/05611; H01L 2224/05644; H01L 2224/0569; H01L 2224/02311; H01L 2224/05124

(57) ABSTRACT

A method to fabricate a land grid array wafer level chip scale package is described. A plurality of silicon dies are provided on a wafer. Openings are etched through a dielectric layer to metal pads on the silicon dies. At least one redistribution layer is formed over the dielectric layer and contacting at least one metal pad. A second dielectric layer is deposited on the at least one redistribution layer. An opening is etched through the second dielectric layer to the at least one redistribution layer and a landing pad is formed on the redistribution layer in the opening. The landing pad may be a portion of the redistribution layer exposed by the opening. Alternatively, the landing pad may be an under bump metal (UBM) layer deposited on the exposed redistribution layer and patterned. The landing pad is covered with an oxidation preventing layer.

### RELATED PATENT APPLICATION

This disclosure is related to U.S. patent application Ser. No. 15/835,580 filed on Dec. 8, 2017 and herein incorporated by reference in its entirety.

### (1) TECHNICAL FIELD

This disclosure is related to wafer packaging technologies, and more particularly, to improved wafer level chip scale packaging.

### (2) BACKGROUND

Solder balls as a BGA (ball grid array) in current wafer level chip scale packages (WLCSP), also known as wafer level ball grid array (WLBGA) packages, are used to connect to a PCB (printed circuit board). Extra tooling (stencil) and processes including ball placement, flux printing, clean, and reflow need to be implemented to prepare solder balls.

U.S. Patent Application 2017/0278765 (Strothmann et al) and U.S. Pat. No. 9,520,342 (Michael et al), U.S. Pat. No. 9,431,332 (Park), U.S. Pat. No. 7,525,167 (Shizuno), U.S. Pat. No. 6,784,535 (Chiu), U.S. Pat. No. 9,754,867 (Lin et al), and U.S. Pat. No. 7,576,436 (Hung) show various types of packages.

### SUMMARY

It is the primary objective of the present disclosure to provide a wafer level chip scale package with land grid array (LGA) connection to a printed circuit board (PCB).

It is another objective of the disclosure to provide a wafer level chip scale package with land grid array (LGA) connection to a printed circuit board (PCB) and removing the under ball metal (UBM) layer as well to reduce packaging cost.

It is yet another objective of the disclosure to provide a process for fabricating a wafer level chip scale package with land grid array (LGA) connection to a printed circuit board (PCB).

It is a further objective of the disclosure to provide a process for fabricating a wafer level chip scale package with land grid array (LGA) connection to a printed circuit board (PCB) and no under ball metal (UBM) layer.

In accordance with the objectives of the present disclosure, a land grid array wafer level chip scale package is achieved. The package comprises a silicon die at a bottom of the package, at least one redistribution layer connected to the silicon die through an opening through a dielectric layer to a metal pad on a top surface of the silicon die, and at least one under bump metal (UBM) layer contacting the at least one redistribution layer and forming a land grid array wherein an oxidation preventing layer is formed on the UBM layer. Alternatively, no UBM layer is provided, but a portion of the at least one redistribution layer exposed through an opening in a second dielectric layer and covered with an oxidation preventing layer forms the land grid array.

Also in accordance with the objectives of the present disclosure, a method to fabricate a land grid array wafer level chip scale package is achieved. A plurality of silicon dies are provided on a wafer. Openings are etched through a dielectric layer to metal pads on the silicon dies. At least one redistribution layer is formed over the dielectric layer and contacting at least one metal pad. A second dielectric layer is deposited on the at least one redistribution layer. An opening is etched through the second dielectric layer to the at least one redistribution layer and a landing pad is formed on the redistribution layer in the opening. The landing pad may be a portion of the redistribution layer exposed by the opening. Alternatively, the landing pad may be an under bump metal (UBM) layer deposited on the exposed redistribution layer and patterned. The landing pad is covered with an oxidation preventing layer.

### BRIEF DESCRIPTION OF THE DRAWINGS

In the accompanying drawings forming a material part of this description, there is shown:

FIG. 1 is a cross-sectional representation of wafer level chip scale package of the prior art.

FIG. 2 is a cross-sectional representation of a wafer level chip scale package of a first preferred embodiment of the present disclosure.

FIG. 3 is a cross-sectional representation of a wafer level chip scale package of a second preferred embodiment of the present disclosure.

FIGS. 4-8 are cross-sectional representations of steps in fabricating a wafer level chip scale package of the first preferred embodiment of the present disclosure.

FIGS. 9-12 are cross-sectional representations of steps in fabricating a wafer level chip scale package of the second preferred embodiment of the present disclosure.

FIG. 13 is a cross-sectional representation of the attachment structures between a wafer level chip scale package of the present disclosure and a printed circuit board.

### DETAILED DESCRIPTION

The present disclosure describes a structure and a process in which the ball grid array (BGA) in a wafer level chip scale package (WLCSP) is replaced by a land grid array (LGA) to reduce the package cost and process cycle time. One of the functions of solder balls is to provide solder volume for the interconnection between the package and the printed circuit board (PCB). If enough solder paste volume can be provided in the surface mount technology (SMT) process, the interconnection will not be an issue and solder balls can be eliminated. Furthermore, the under bump metal (UBM) layer may be omitted for further cost reduction, particularly in connectivity applications (such as Wi-fi and bluetooth) in which high current is not required.

Other advantages of the WLCSP of the present disclosure include:

1. Lower package cost.

2. Reduced process cycle time (time to market early).

3. Improved package reliability as evidenced by improved Board Level Reliability (BLR) drop test performance with lower package stand-off height.

4. These features may be used in embedding or fan out of the WLCSP in System in Package (SiP) modules.

FIG. 1 illustrates a traditional WLCSP (WLBGA) in the production stage. An opening is made to the aluminum pad 12 on the die 10 through the die passivation layer 14. First dielectric layer 16 is deposited, then patterned to provide an opening for the RDL layer 18. Second dielectric layer 20 is deposited over the patterned RDL. Dielectric layer 20 is patterned to form an opening for the UBM 22 which is also patterned. Solder ball 24 is placed onto the UBM. There are total of four photo masks (dielectric layer 1, RDL, dielectric layer 2, UBM) and two stencils (flux & ball) required to complete this package.

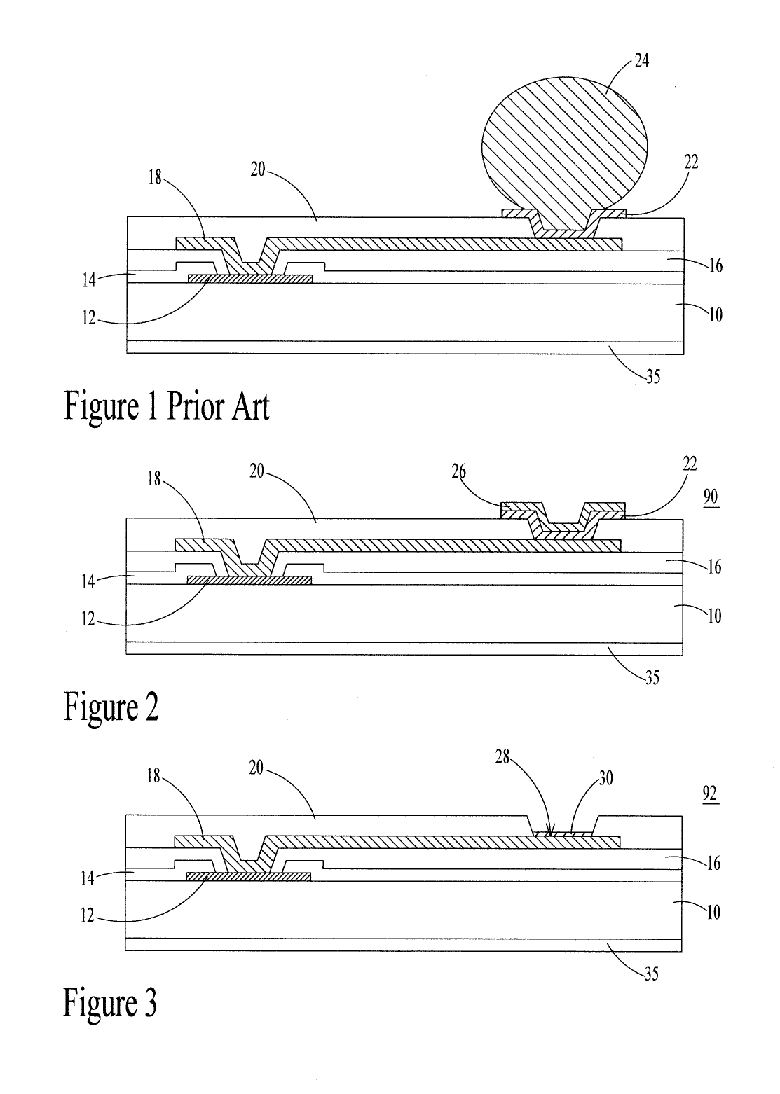

FIG. 2 illustrates a first preferred embodiment of the present disclosure in which the solder ball 24 is removed. This package is a wafer level UBM grid array (WLUGA). The presence of the UBM 22 provides excellent electrical performance. A protective layer 26 is coated, printed, or plated onto the UBM surface to prevent pad oxidation.

FIG. 3 illustrates a second preferred embodiment of the present disclosure. This embodiment is a wafer level pad grid array (WLPGA). Here, the UBM layer is omitted for a further cost reduction. A portion of the RDL layer 18 serves as the pad 28. Protective layer 30 is coated, printed, or plated onto the pad 28 surface to prevent pad oxidation and preserve its solderability onto the printed circuit board (PCB).

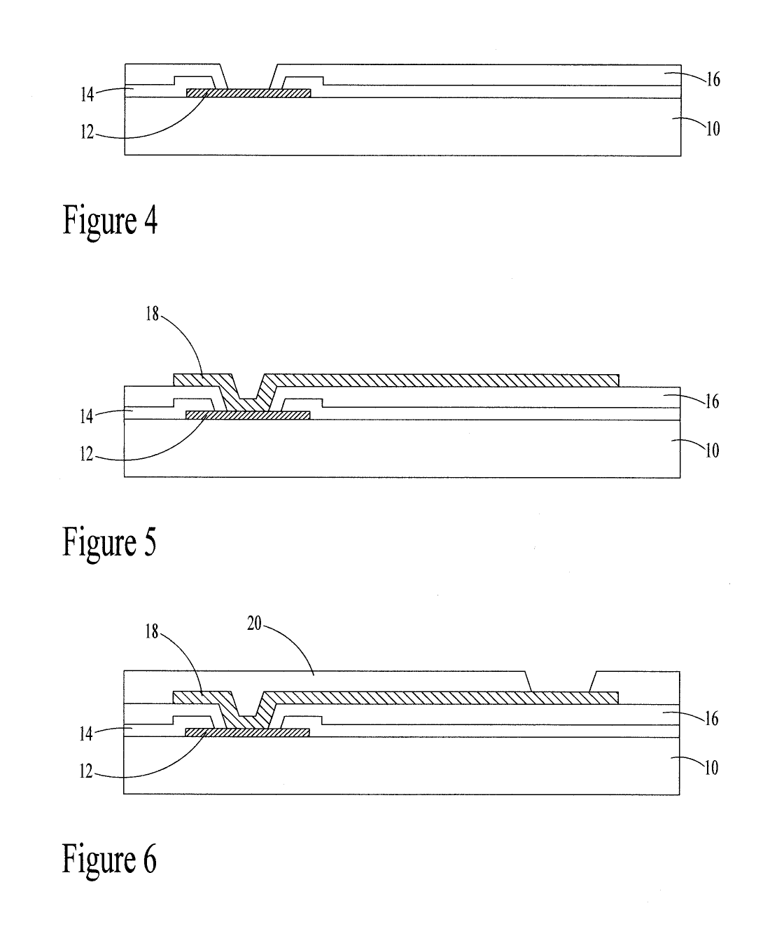

The process of fabricating the packages of the present disclosure will be described in detail with reference to FIGS. 4-8 for the first preferred embodiment and with reference to FIGS. 9-12 for the second preferred embodiment. Referring now more particularly to FIGS. 4-8, the process of fabricating a WLUGA of the first preferred embodiment of the present disclosure will be described.

As illustrated in FIG. 4, the package of the present disclosure is fabricated similarly to the traditional package. An opening is made to the aluminum pad 12 on the die 10 through the die passivation layer 14; for example, silicon nitride (SiN). First dielectric layer 16 is deposited, then patterned to provide an opening for the RDL layer 18. RDL layer 18 is deposited and patterned as shown in FIG. 5.

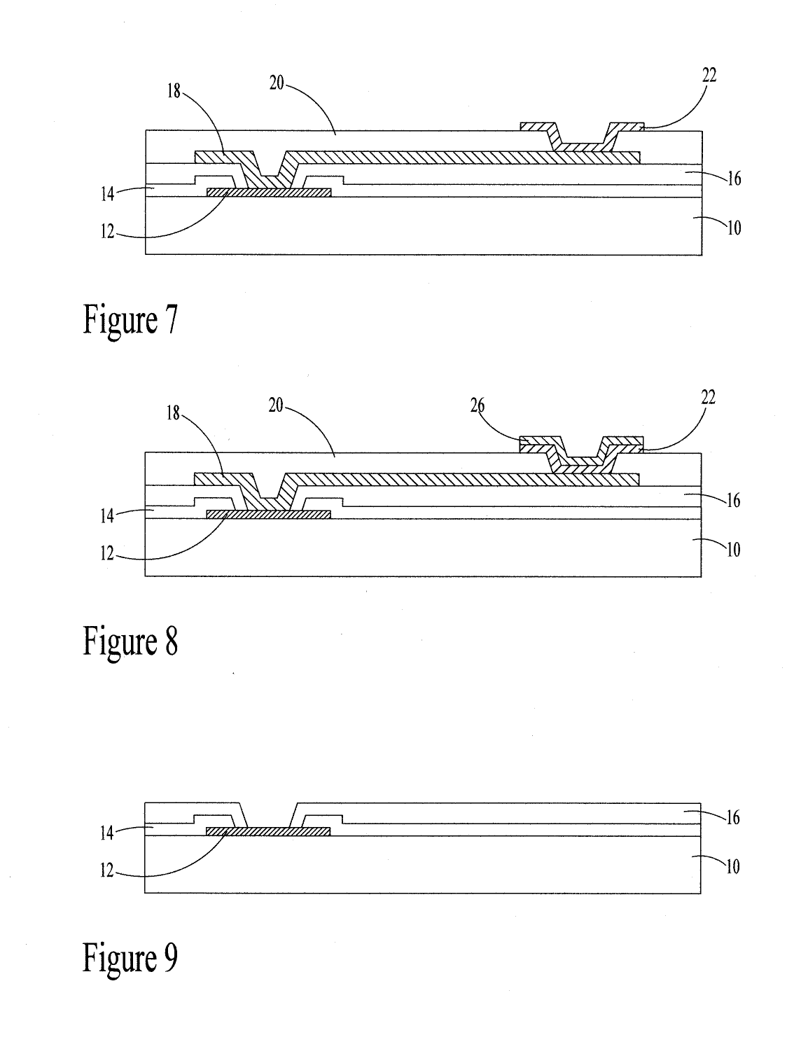

Now, second dielectric layer 20 is deposited over the patterned RDL layer 18, as shown in FIG. 6, and patterned to provide an opening for the underbump metal (UBM) layer. UBM layer 22 is deposited and patterned as shown in FIG. 7. UBM 22 will provide a landing pad for connection to a PCB.

Referring now to FIG. 8, a protective layer 26 such as organic solderability preservatives (OSP), immersion tin (IT), or an electroplated gold layer is coated, printed, or plated onto the exposed UBM layer surfaces to prevent pad oxidation prior to the surface mount technology (SMT) process onto the printed circuit board (PCB).

Next, the backside of the wafer is thinned. An optional backside film 35 may be laminated onto the backside of the wafer, as shown in FIG. 2. The backside, such as an epoxy material, is laminated onto the wafer backside and cured, for example, at 130° C. for 2 hours. The extra backside film 35 protects the silicon backside and edge from chipping caused by the wafer die saw process. The wafer is now singulated into package form. FIG. 2 shows the competed package 90 with the optional backside film 35.

Referring now more particularly to FIGS. 9-12, the process of fabricating a WLPGA of the second preferred embodiment of the present disclosure will be described.

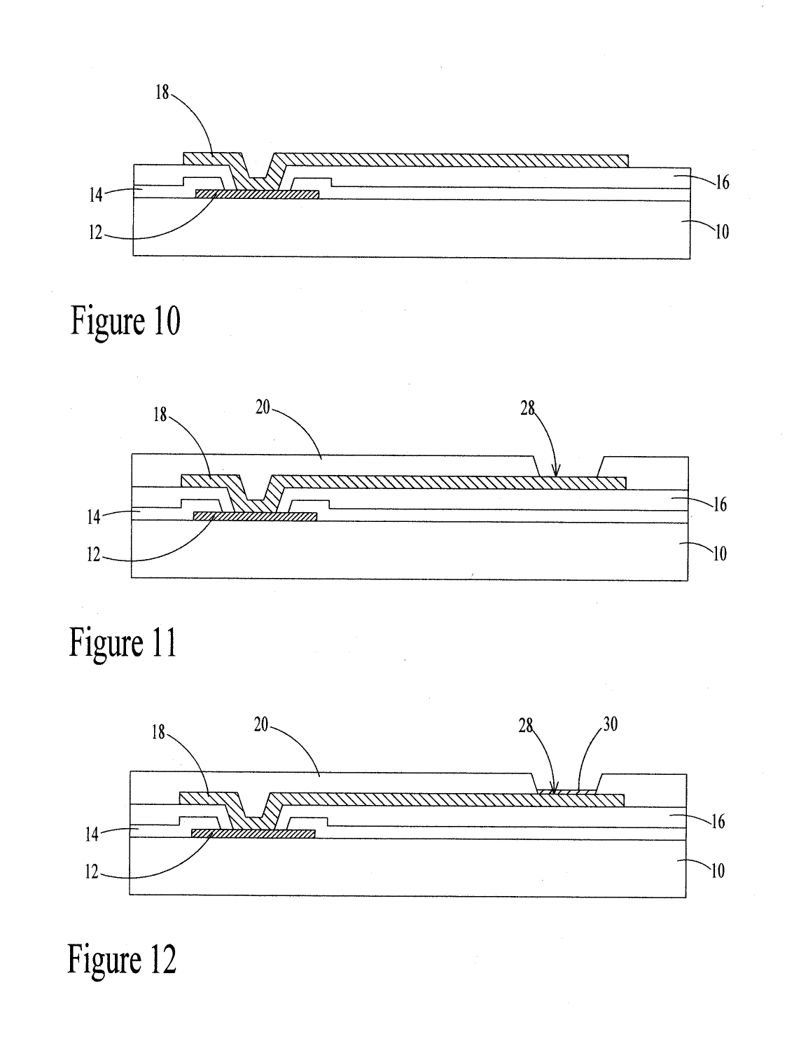

As illustrated in FIG. 9, the package of the present disclosure is fabricated similarly to the traditional package. An opening is made to the aluminum pad 12 on the die 10 through the die passivation layer 14; for example, silicon nitride (SiN). First dielectric layer 16 is deposited, then patterned to provide an opening for the RDL layer 18. RDL layer 18 is deposited and patterned as shown in FIG. 10.

Now, second dielectric layer 20 is deposited over the patterned RDL layer 18, as shown in FIG. 11, and patterned to provide an opening to the RDL layer. The exposed RDL layer in the opening will provide a landing pad 28 for connection to a PCB.

Referring now to FIG. 12, a protective layer 30 such as organic solderability preservatives (OSP), immersion tin (IT), or an electroplated gold layer is coated, printed, or plated onto the exposed pad surface 28 to prevent pad oxidation prior to the surface mount technology (SMT) process onto the printed circuit board (PCB).

Next, the backside of the wafer is thinned. An optional backside film 35 may be laminated onto the backside of the wafer. Processing continues as described in the first embodiment. FIG. 3 shows the competed package 92 with the optional backside film 35.

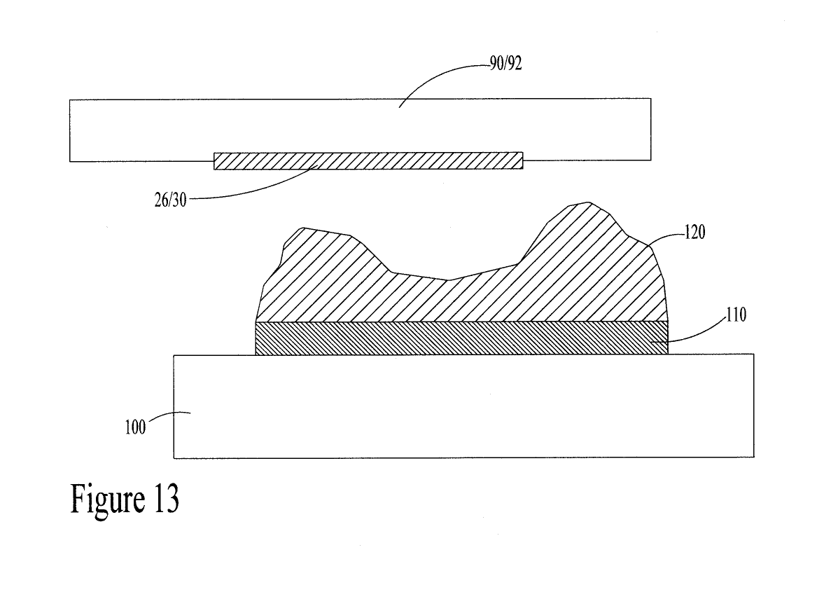

In backend processing, according to both preferred embodiments of the present disclosure, the wafer is prepared for connection to a printed circuit board. In the process of the present disclosure, UBM 22 with coating 26 or RDL landing pad 28 with coating 30 comprise a land grid array for attaching a printed circuit board (PCB). FIG. 13 illustrates a PCB 100 having a pad 110. Solder paste 120 printing volume can be controlled by solder paste stencil aperture sizes and thickness design to get a better solder joint where the solder paste 120 bonds with the landing pad 26/30 of the package 90/92 of the present disclosure.

LGA devices of the present disclosure can be used for either lead containing or lead-free assemblies depending on the surface mount technology (SMT) assembly solder paste used. LGA eliminates risk that customers receive components with missing or damaged spheres (solder balls) due to shipping or handling. LGA devices have a lower mounted height than BGA. This can allow for more space above the device for a heat sink solution or for small form-factor applications. A WLCSP fabricated according to the process of the present disclosure results in a board-level reliability significantly exceeding customer requirements.

Replacing BGA with LGA saves package cost and process cycle time as well as reducing the package height. Omitting the UBM layer pad in the second preferred embodiment and using a portion of the RDL layer as a landing pad further reduces cost and cycle time.

Although the preferred embodiment of the present disclosure has been illustrated, and that form has been described in detail, it will be readily understood by those skilled in the art that various modifications may be made therein without departing from the spirit of the disclosure or from the scope of the appended claims.

What is claimed is:

1. A land grid array wafer level chip scale package comprising:
a silicon die at a bottom of said package;
at least one redistribution layer connected to said silicon die through an opening through a dielectric layer to a metal pad on a top surface of said silicon die; and
at least one under bump metal (UBM) layer contacting said at least one redistribution layer and forming a land grid array wherein an oxidation preventing layer is formed on said UBM layer.

2. The package according to claim 1 wherein said oxidation preventing layer comprises organic solderability preservatives (OSP), immersion tin (IT), or electroplated gold.

3. The package according to claim 1 wherein a printed circuit board is mounted onto said package via said land grid array.

4. A land grid array wafer level chip scale package comprising:
a silicon die at a bottom of said package;
at least one redistribution layer connected to said silicon die through an opening through a dielectric layer to a metal pad on a top surface of said silicon die; and
a second dielectric layer covering said at least one redistribution layer wherein a portion of said at least one redistribution layer is exposed forming a land grid array wherein an oxidation preventing layer is formed on said exposed at least one redistribution layer.

5. The package according to claim 4 wherein said oxidation preventing layer comprises organic solderability preservatives (OSP), immersion tin (IT), or electroplated gold.

6. The package according to claim 4 wherein a printed circuit board is mounted onto said package via said land grid array.

7. A method of fabricating a land grid array wafer level chip scale package comprising:
providing a plurality of silicon dies on a wafer;
depositing a first dielectric layer on said plurality of silicon dies;
etching an opening through said first dielectric layer to metal pads on said silicon dies;
forming at least one redistribution layer over said dielectric layer and contacting at least one said metal pad;
depositing a second dielectric layer on said at least one redistribution layer;
etching an opening through said second dielectric layer to said at least one redistribution layer; and
forming a landing pad on said redistribution layer in said opening.

8. The method according to claim 7 wherein said forming said landing pad on said redistribution layer comprises:
depositing an under bump metal (UBM) layer on said at least one redistribution layer exposed within said opening;
patterning said UBM layer; and
forming an oxidation preventing layer on patterned said UBM layer to complete said landing pad.

9. The method according to claim 8 wherein said oxidation preventing layer comprises organic solderability preservatives (OSP), immersion tin (IT), or electroplated gold coated, printed, or plated onto exposed said UBM layer.

10. The method according to claim 7 wherein said forming said landing pad on said redistribution layer comprises:
forming an oxidation preventing layer on said at least one redistribution layer exposed within said opening to complete said landing pad.

11. The method according to claim 10 wherein said oxidation preventing layer comprises organic solderability preservatives (OSP), immersion tin (IT), or electroplated gold coated, printed, or plated onto exposed said redistribution layer.

12. The method according to claim 7 further comprising:
thinning a backside of said wafer; and
thereafter singulating said wafer to form packages.

13. The method according to claim 12 further comprising laminating a backside protection film onto thinned said backside of said wafer prior to said singulating step.

14. The method according to claim 13 wherein said backside protection film comprises epoxy.

15. The method according to claim 7 further comprising:
providing at least one pad on a printed circuit board;
applying solder paste on said at least one pad; and
surface mounting said landing pad of said wafer level chip scale package to said at least one pad on said printed circuit board via said solder paste.
